(19) United States
(12) Patent Application Publication
(10) Pub. No.: US 2025/0323125 A1
(43) Pub. Date: Oct. 16, 2025

(54) SEMICONDUCTOR DEVICE WITH BACKSIDE INTERFACE MECHANISM AND METHODS FOR MANUFACTURING THE SAME

(71) Applicant: Micron Technology, Inc., Boise, ID (US)

(72) Inventors: Bharat Bhushan, Taichung (TW); Jonathan A. Bennett, American Fork, UT (US); Kunal R. Parekh, Boise, ID (US); Akshay N. Singh, Boise, ID (US); Terrence B. McDaniel, Boise, ID (US)

(21) Appl. No.: 19/176,765

(22) Filed: Apr. 11, 2025

Related U.S. Application Data
(60) Provisional application No. 63/633,630, filed on Apr. 12, 2024.

(51) Int. Cl. H01L 23/48; H01L 21/768; H01L 23/00; H01L 25/00; H01L 25/16; H10B 80/00

(52) U.S. Cl. CPC H01L 23/481; H01L 21/76898; H01L 24/03; H01L 24/05; H01L 24/08; H01L 25/16; H01L 25/50; H01L 2224/03602; H01L 2224/0557; H01L 2224/08145; H01L 2224/08225; H10B 80/00

(57) ABSTRACT

Methods, apparatuses, and systems related to a memory device having on its backside one or more integrally-formed structures is described. A memory device may have on a backside of a semiconductor substrate an integral electrical connector that includes (1) a pad portion configured to connect to an external component and (2) a through-silicon via (TSV) portion that at least partially extends through the semiconductor substrate. The pad portion and the TSV portion may be connected through an integral joint. The TSV portion can have a narrowing shape with its cross-sectional width decreasing for portions farther away from the pad portion.

### CROSS-REFERENCE TO RELATED APPLICATION(S)

The present application claims priority to U.S. Provisional Patent Application No. 63/633,630, filed Apr. 12, 2024, the disclosure of which is incorporated herein by reference in its entirety.

### TECHNICAL FIELD

The disclosed embodiments relate to devices, and, in particular, to semiconductor devices with backside interface mechanism and methods for manufacturing the same.

### BACKGROUND

A semiconductor device can include one or more circuits, such as a combination of connected transistors, capacitors, and other similar circuit components, fabricated or embedded in semiconductor material. Some examples of the semiconductor device can include a semiconductor die, a package, a system-on-chip, a circuit card, or the like including the semiconductor-based circuits. Such semiconductor device can be configured for a variety of functions, as for a processor or a memory device (e.g., a volatile memory device, a non-volatile memory device, or a combination device).

With technological growth and increasing applications, the market is continuously looking for faster, more efficient, and smaller devices. To meet the market demand, the semiconductor devices are being pushed to the limit with various improvements. Improving devices, generally, may include increasing circuit density, reducing the circuit footprint, increasing operating speeds or otherwise reducing operational latency, increasing reliability, reducing power consumption, or reducing manufacturing costs, among other metrics. For example, three-dimensional (3D) architectures are being researched for semiconductor device designs.

### BRIEF DESCRIPTION OF THE DRAWINGS

FIG. 1 is a block diagram of an apparatus in accordance with an embodiment of the present technology.

FIG. 2 is a cross-sectional view of a first semiconductor device in accordance with an embodiment of the present technology.

FIG. 3 is a cross-sectional view of a second semiconductor device in accordance with an embodiment of the present technology.

FIGS. 4A-4J are illustrations of various stages of a first example manufacturing process in accordance with an embodiment of the present technology.

FIGS. 5-11 are illustrations of various stages of a second example manufacturing process in accordance with an embodiment of the present technology.

FIGS. 12A-12C are cross-sectional views of various example assemblies in accordance with an embodiment of the present technology.

FIG. 13 is a flow diagram illustrating an example method of manufacturing a semiconductor device with a BS routing mechanism in accordance with an embodiment of the present technology.

FIG. 14 is a schematic view of a system that includes a semiconductor device in accordance with an embodiment of the present technology.

### DETAILED DESCRIPTION

As described in greater detail below, the technology disclosed herein relates to a semiconductor device having a backside (BS) interfacing mechanism, such as for memory systems, systems with memory devices, etc., and related methods. The BS interfacing mechanism can include a pad portion and a Through-Silicon Via (TSV) portion, integral to each other and formed on the BS of a semiconductor substrate. The integral structure can include the pad portion configured to provide an external communication interface with a device attached thereto. The TSV portion of the integral structure can be configured to provide a vertical electrical connection between the pad portion and the frontside (FS) of the semiconductor substrate, such as to active circuitry patterned on the FS, one of back end of line (BEOL) metal layers, and/or external pads located on the FS. The BS interfacing mechanism can have an integral joint between the pad portion and the TSV portion, such as resulting from a single forming step. For example, the BS interfacing mechanism can be formed using a continuous metallization process, such as a dual-damascene (DD) process, that forms both portions continuously and without including any intervening and without any portion-specific formation/deposit processes.

In some embodiments, the BS interfacing mechanism can be formed after thinning the semiconductor substrate. In other words, BS interfacing mechanism can be formed by operating on a thinned semiconductor wafer. As a result, the BS interfacing mechanism can have a shape that narrows towards the FS (e.g., having a maximum width at the integral joint) and maintains a narrower width than that of the pad portion.

The BS interfacing mechanism can provide a narrower pitch between external interfaces (e.g., pads or pad portions) and a narrower pitch between vertical vias within a semiconductor device (e.g., a chip). Accordingly, the corresponding device or a package or an assembly having the BS interfacing mechanism can have an increased number of signals within a given area, thereby increasing the signal density. The narrower TSV portions and the increased density can reduce the resistance provided by the signal paths, and thus reduce the power consumption, the related thermal energy, and the noise susceptibility for the overall semiconductor device. Moreover, the reduced power consumption, the reduced interface pitch, and the like can enable the semiconductor to be directly stacked on different devices, such as logic dies or processor chips.

Further, the method for manufacturing the BS interfacing mechanism can (1) eliminate traditional manufacturing steps, such as the separate FS-based via formation and the BS reveal of such vias, and (2) leverage and rearrange existing manufacturing processes, such as for masking, etching, patterning, and the like (e.g., corresponding to the DD process). Accordingly, the BS interfacing mechanism can reduce the overall manufacturing cost and duration.

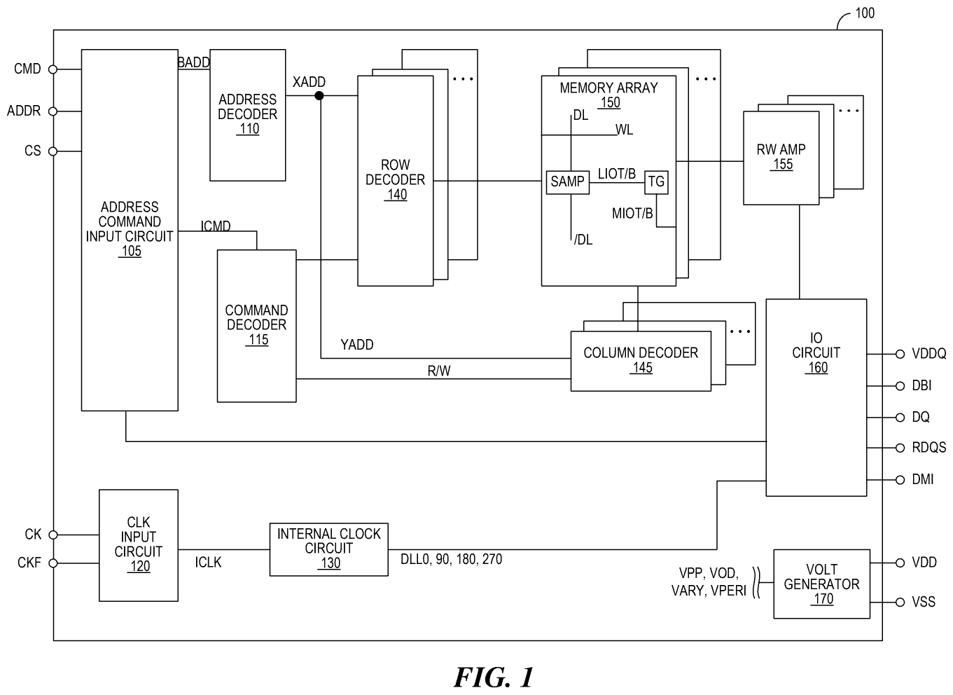

FIG. 1 is a block diagram of an apparatus 100 (e.g., a semiconductor die assembly, including a three-dimensional integration (3DI) device or a die-stacked package) in accordance with an embodiment of the present technology. For example, the apparatus 100 can include a DRAM, a NAND, a CPU, a GPU, one or more chiplets, or a portion thereof that includes one or more dies/chips.

The apparatus 100 may include an array of memory cells, such as memory array 150. The memory array 150 may include a plurality of banks (e.g., banks 0-15), and each bank may include a plurality of WLs, a plurality of DLs, and a plurality of memory cells arranged at intersections of the word-lines and the bit lines. Memory cells can include any one of a number of different memory media types, including capacitive, magnetoresistive, ferroelectric, phase change, or the like. In some aspects, the memory cells are capacitive. Additionally, the memory array 150 may be formed using one or more memory dies that are stacked. Details regarding the structure of the WLs, the DLs, and the memory cells are described below.

The selection of a word-line WL may be performed by a row decoder 140, and the selection of a digit-line DL may be performed by a column decoder 145. Sense amplifiers (SAMP) may be provided for coupled digit-line DL and connected to at least one respective local I/O line pair (LIOT/B), which may in turn be coupled to at least respective one main I/O line pair (MIOT/B), via transfer gates (TG), which can function as switches. The sense amplifiers and transfer gates may be operated based on control signals from decoder circuitry, which may include the command decoder 115, the row decoders 140, the column decoders 145, any control circuitry of the memory array 150, or any combination thereof. The memory array 150 may also include plate lines and related circuitry for managing their operation.

The apparatus 100 may employ a plurality of external terminals that include command and address terminals coupled to a command bus and an address bus to receive command signals (CMD) and address signals (ADDR), respectively. The apparatus 100 may further include a chip select terminal to receive a chip select signal (CS), clock terminals to receive clock signals CK and CKF, data clock terminals to receive data clock signals WCK and WCKF, data terminals DQ, RDQS, DBI, DMI, power supply terminals VDD, VSS, and VDDQ.

The command terminals and address terminals may be supplied with an address signal and a bank address signal (not shown in FIG. 1) from outside. The address signal and the bank address signal supplied to the address terminals can be transferred, via a command/address (CA) input circuit 105, to an address decoder 110. The address decoder 110 can receive the address signals and supply a decoded row address signal (XADD) to the row decoder 140, and a decoded column address signal (YADD) to the column decoder 145. The address decoder 110 can also receive the bank address signal and supply the bank address signal to both the row decoder 140 and the column decoder 145.

The command and address terminals may be supplied with command signals (CMD), address signals (ADDR), and chip select signals (CS), from a memory controller and/or a nefarious chipset. The command signals may represent various memory commands from the memory controller (e.g., including access commands, which can include read commands and write commands). The chip select signal may be used to select the apparatus 100 to respond to commands and addresses provided to the command and address terminals. When an active chip select signal is provided to the apparatus 100, the commands and addresses can be decoded, and memory operations can be performed. The command signals may be provided as internal command signals ICMD to a command decoder 115 via the command/address input circuit 105. The command decoder 115 may include circuits to decode the internal command signals ICMD to generate various internal signals and commands for performing memory operations, for example, a row command signal to select a word-line and a column command signal to select a bit line. The command decoder 115 may further include one or more registers for tracking various counts or values (e.g., counts of refresh commands received by the apparatus 100 or self-refresh operations performed by the apparatus 100).

Read data can be read from memory cells in the memory array 150 designated by row address (e.g., address provided with an active command) and column address (e.g., address provided with the read). The read command may be received by the command decoder 115, which can provide internal commands to input/output circuit 160 so that read data can be output from the data terminals DQ, RDQS, DBI, and DMI via read/write amplifiers 155 and the input/output circuit 160 according to the RDQS clock signals. The read data may be provided at a time defined by read latency information RL that can be programmed in the apparatus 100, for example, in a mode register (not shown in FIG. 1). The read latency information RL can be defined in terms of clock cycles of the CK clock signal. For example, the read latency information RL can be a number of clock cycles of the CK signal after the read command is received by the apparatus 100 when the associated read data is provided.

Write data can be supplied to the data terminals DQ, DBI, and DMI according to the WCK and WCKF clock signals. The write command may be received by the command decoder 115, which can provide internal commands to the input/output circuit 160 so that the write data can be received by data receivers in the input/output circuit 160 and supplied via the input/output circuit 160 and the read/write amplifiers 155 to the memory array 150. The write data may be written in the memory cell designated by the row address and the column address. The write data may be provided to the data terminals at a time that is defined by write latency WL information. The write latency WL information can be programmed in the apparatus 100, for example, in the mode register. The write latency WL information can be defined in terms of clock cycles of the CK clock signal. For example, the write latency information WL can be a number of clock cycles of the CK signal after the write command is received by the apparatus 100 when the associated write data is received.

The power supply terminals may be supplied with power supply potentials V_{DD} and V_{SS}. These power supply potentials V_{DD} and V_{SS} can be supplied to an internal voltage generator circuit 170. The internal voltage generator circuit 170 can generate various internal potentials V_{PP}, V_{OD}, V_{ARY}, VP_{ERI}, and the like based on the power supply potentials V_{DD} and V_{SS}. The internal potential V_{PP} can be used in the row decoder 140, the internal potentials V_{OD} and V_{ARY} can be used in the sense amplifiers included in the memory array 150, and the internal potential V_{PERI} can be used in many other circuit blocks.

The power supply terminal may also be supplied with power supply potential V_{DDQ}. The power supply potential V_{DDQ} can be supplied to the input/output circuit 160 together with the power supply potential VSS. The power supply potential V_{DDQ} can be the same potential as the power supply potential V_{SS} in an embodiment of the present technology. The power supply potential V_{DDQ} can be a different potential from the power supply potential V_{DD} in another embodiment of the present technology. However, the dedicated power supply potential V_{DDQ} can be used for the input/output circuit 160 so that power supply noise generated by the input/output circuit 160 does not propagate to the other circuit blocks.

The clock terminals and data clock terminals may be supplied with external clock signals and complementary external clock signals. The external clock signals CK, CKF, WCK, WCKF can be supplied to a clock input circuit 120. The CK and CKF signals can be complementary, and the WCK and WCKF signals can also be complementary. Complementary clock signals can have opposite clock levels and transition between the opposite clock levels at the same time. For example, when a clock signal is at a low clock level a complementary clock signal is at a high level, and when the clock signal is at a high clock level the complementary clock signal is at a low clock level. Moreover, when the clock signal transitions from the low clock level to the high clock level the complementary clock signal transitions from the high clock level to the low clock level, and when the clock signal transitions from the high clock level to the low clock level the complementary clock signal transitions from the low clock level to the high clock level.

Input buffers included in the clock input circuit 120 can receive the external clock signals. For example, when enabled by a clock/enable signal from the command decoder 115, an input buffer can receive the clock/enable signals. The clock input circuit 120 can receive the external clock signals to generate internal clock signals ICLK. The internal clock signals ICLK can be supplied to an internal clock circuit 130. The internal clock circuit 130 can provide various phase and frequency controlled internal clock signals based on the received internal clock signals ICLK and a clock enable (not shown in FIG. 1) from the command/address input circuit 105. For example, the internal clock circuit 130 can include a clock path (not shown in FIG. 1) that receives the internal clock signal ICLK and provides various clock signals to the command decoder 115. The internal clock circuit 130 can further provide input/output (IO) clock signals. The IO clock signals can be supplied to the input/output circuit 160 and can be used as timing signals for determining output timing of read data and/or input timing of write data. The IO clock signals can be provided at multiple clock frequencies so that data can be output from and input to the apparatus 100 at different data rates. A higher clock frequency may be desirable when high memory speed is desired. A lower clock frequency may be desirable when lower power consumption is desired. The internal clock signals ICLK can also be supplied to the internal clock circuit 130 and thus various internal clock signals can be generated.

The apparatus 100 can be connected to any one of a number of electronic devices capable of utilizing memory for the temporary or persistent storage of information, or a component thereof. For example, a host device of apparatus 100 may be a computing device such as a desktop or portable computer, a server, a hand-held device (e.g., a mobile phone, a tablet, a digital reader, a digital media player), or some component thereof (e.g., a central processing unit, a co-processor, a dedicated memory controller, etc.). The host device may be a networking device (e.g., a switch, a router, etc.) or a recorder of digital images, audio and/or video, a vehicle, an appliance, a toy, or any one of a number of other products. In one embodiment, the host device may be connected directly to apparatus 100; although in other embodiments, the host device may be indirectly connected to memory device (e.g., over a networked connection or through intermediary devices).

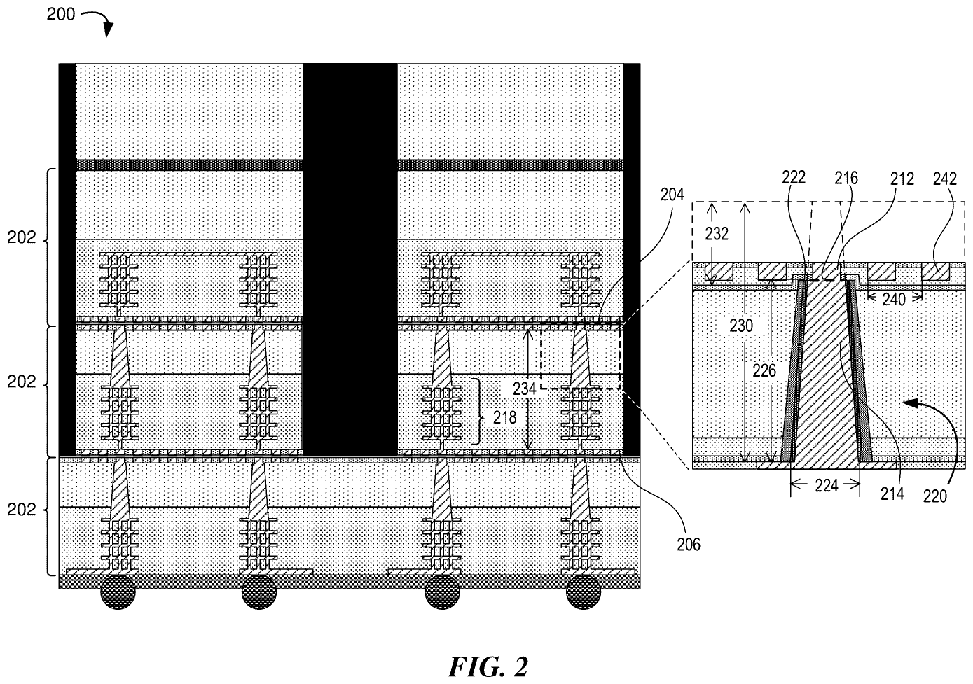

FIG. 2 is a cross-sectional view of a semiconductor device 200 (e.g., a stacked package) in accordance with an embodiment of the present technology. The semiconductor device 200 can include a set of smaller devices, such as semiconductor chips 202, stacked on top of each other. For example, one or more stacks of semiconductor memory devices can be mounted over a logic device. In another example, one or more stacks of semiconductor memory devices can be mounted on a CPU/GPU device. Each of the semiconductor chips 202 can have a backside (BS) 204 opposite a frontside (FS) 206, and a mounted chip can have the FS 206 opposite/facing the BS 204 of the bottom chip. The semiconductor device 200 can include a mold or an encapsulant surrounding or encasing the semiconductor chips 202 or portions thereof. In some embodiments, the material that is forming the surrounding of semiconductor chips 202 is silicon oxide.

The stacked devices can be physically attached to other devices within the stack. For example, the stacked devices can be attached through wafer-to-wafer bonding, chip-to-wafer bonding, stack-to-wafer bonding, or the like. Accordingly, the stacked devices can be directly attached to each other, such as without using posts/pillars and/or solder between the vertically adjacent devices (e.g., wafers or chips). In some aspects, the stacked devices can be directly attached to each other via copper-to-copper (Cu2Cu) hybrid bonding.

The stacked devices can be electrically coupled along vertical directions. For example, each of the semiconductor chips 202 can have pads 212 on the FS 206 and/or the BS 204 thereof. The pads 212 can be configured to provide electrical interface between the corresponding semiconductor chips 202 and/or or between semiconductor device 200 and external devices/circuits. The pads 212 can be configured to physically attach to and electrically couple with solder, wires, pads on other chips, or the like.

Each of the semiconductor chips 202 can further include through-silicon vias (TSVs) 214 extending across a semiconductor wafer within the chip. The TSVs 214 can extend across a thickness of the semiconductor wafer, such as between the BS 204 and the FS 206. In some embodiment, the TSVs 214 are formed using the via-middle TSV process, where the TSVs are formed when middle of the line (MOL) is formed. In other words, the TSVs are formed after the formation of transistors and before the formation of the metal lines. The TSVs 214 can be electrically coupled to the pads 212 on the BS 204 and active circuitry, the pads 212 on the FS 206, one or more signal routing layers 218, or a combination thereof on/within the corresponding semiconductor chip. The signal routing layers 218 can include electrically conductive structures configured to extend the electrical connections along lateral and/or vertical directions. For the example illustrated in FIG. 2, the memory chips in the middle layer and the logic device on the bottom layer can include the signal routing layers 218 on the FS 206.

One or more of the TSVs 214 can be physically attached to one or more of the pads 212 and form detectable joints 216. The detectable joints 216 can include physical separations, inconsistencies in the thickness or consistency of material, or the like between the connected pad and TSV. Each of the detectable joints 216 can correspond to a result of forming the TSVs 214 using a process/step separate (e.g., in time and/or having one or more intervening manufacturing processes/steps in between) from a process/step used to form the pads 212. In some embodiments, the pads 212 may be formed using a single damascene process, and TSVs 214 are formed using another single damascene process.

In some embodiments, the TSVs 214 can have a widening via shape 220 and/or a via shoulder 222 characteristic of forming the TSVs 214 from the FS 206 toward the BS 204 and/or before any wafer thinning process. The widening via shape 220 can correspond to cross-sectional widths of the TSV increasing toward the FS 206 and at portions farther from the BS 204. For example, the narrowest width of the TSV can be at the detectable joint 216, and the widest width of the TSV at the FS 206 and/or the signal routing layer 218. Accordingly, the side/profile shape of the TSV can include a trapezoid with a narrower top portion as illustrated in FIG. 2.

Further, the via shoulder 222 can include peripheral portions of the TSV at the BS 204 that laterally extend past peripheral portions of the connect pads 212. In other words, the portion of the TSV directly under and abutting the corresponding pad can be wider than the pad and extend laterally past the pad.

As an illustrative example, the TSVs 214 can be formed by orienting the FS 206 upward, masking the FS 206, and then applying etchants through openings in the FS mask. Accordingly, the FS portions of the semiconductor wafer can have greater exposure to the applied etchants in comparison to the BS portions. As a result, the resulting TSVs may have greater widths or thicknesses near the FS 206 and narrower widths near the BS 204.

Moreover, in some embodiments, the TSVs 214 can be formed before a wafer thinning process that removes inactive portions of the semiconductor wafer/substrate by a removed thickness 234. After the thinning process the resulting semiconductor wafer can have a final wafer thickness 232 that is less than its initial thickness by the removed thickness 232. Accordingly, the TSVs can have an initial via depth 230 before the thinning and then a final via depth 226 after the thinning. In other words, portions of the via may be removed along with portions of the wafer, such as by chemical and/or mechanical removal mechanisms, to reduce the TSV depth. Given the widening via shape 220 and such manufacturing sequence, the remaining/exposed portion of the TSV on the BS 204 can have a greater lateral dimension than the pads 212 that are subsequently formed on the TSV, thereby resulting in the via shoulders 222.

The widening via shape 220 and/or the via shoulder 222 can affect or provide limitations on a pad pitch 240. The pad pitch 240 can correspond to a lateral spacing or arrangement between the pads 212 on the corresponding side/surface. For example, the pad pitch 240 can correspond to a distance between matching portions or peripheral edges of the pads 212 on the BS 204. Since the widening via shape 220 and the via shoulder 222 both cause the TSVs 214 to extend along lateral directions, they provide limitations on the reducing the pad pitch 240. Accordingly, if the pad pitch 240 is required to be (e.g., according to system or assembly specification) lower or finer than allowed by the widening via shape 220 and/or the via shoulder 222, the semiconductor chips 202 can include dummy pads 242 adjacent to the active pads 212. Stated differently, when external requirements dictate the pad pitch 240 to be finer than two adjacent via maximum widths, the active pads 212 can be separated by one or more dummy pads 242 to secure sufficient footprint or lateral spacing for each of the corresponding TSVs 214.

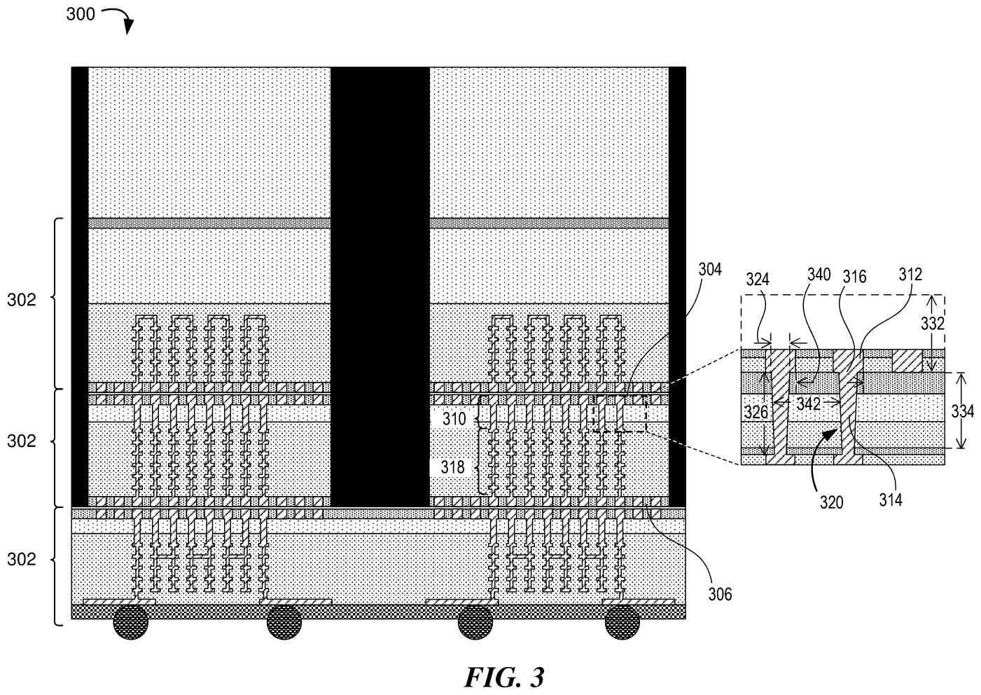

FIG. 3 is a cross-sectional view of a semiconductor device 300 (e.g., a stacked package) in accordance with an embodiment of the present technology. The semiconductor device 300 can have a similar arrangement as the semiconductor device 200 of FIG. 2. For example, the semiconductor device 300 can include a set semiconductor chips 302 (e.g., DRAM chips) stacked on top of each other and/or mounted over a logic device (e.g., an integrated circuit device, such as a semiconductor chip, including interfacing circuitry). In another example, one or more stacks of semiconductor memory devices can be mounted on a CPU/GPU device. The stacked devices can be physically attached to other devices within the stack. For example, the stacked devices can be directly attached (e.g., without intervening or attaching solder, posts, etc.) through wafer-to-wafer bonding, chip-to-wafer bonding, stack-to-wafer bonding, or the like. In some aspects, the stacked devices can be directly attached to each other via copper-to-copper (Cu2Cu) hybrid bonding. Each of the semiconductor chips 302 can have a BS 304 opposite a FS 306. The semiconductor device 300 can include a mold or an encapsulant surrounding or encasing the semiconductor chips 302 or portions thereof. In some embodiments, the material that is forming the surrounding of semiconductor chips 302 is silicon oxide.

The stacked devices can be electrically coupled along vertical directions. For example, each of the semiconductor chips 302 can have external electrical interfaces, such as pads or corresponding structures, on the FS 306 and/or the BS 304 thereof. In some embodiment, the TSVs 314 are formed using the via-last TSV process, where the TSVs are formed after the backend of the line (BEOL) layer has been formed. In other words, the TSVs are formed after the metal layers of the BEOL layer have been formed. The external electrical interfaces can be configured to provide electrical interface between the corresponding semiconductor chip 302, and/or or between semiconductor device 300 and external devices/circuits. The external electrical interfaces can be configured to physically attach to and electrically couple with solder, wires, pads on other chips, or the like.

In some embodiments, one or more of the semiconductor chips 302 can include at least one integral interfacing structure 310. The integral interfacing structure 310 can include a continuously formed and/or uniform (e.g., in density and/or material) electrically conductive structure that is configured to (1) electrically interface with external circuitry and (2) vertically route the corresponding electrical connection across a thickness of the corresponding semiconductor chip 302. The integral interfacing structure 310 can include a pad portion 312 and a TSV portion 314 connected by an integral joint 316. The pad portion 312 can include the external electrical interface similar to a connecting pad. The TSV portion 314 can include a vertically extending at least partially through a semiconductor substrate of the corresponding semiconductor chip 302, such as such as between the BS 304 and the FS 306. The TSV portion 314 can electrically couple the pad portion 312 and the corresponding external circuitry to one or more components, such as active circuitry, pads on the FS 306, and/or one or more signal routing layers 318, on/within the corresponding semiconductor chip. The signal routing layers 318 can include electrically conductive structures configured to extend the electrical connections along lateral and/or vertical directions. In one aspect, the TSV portion 314 can electrically couple the pad portion 312 and a metal layer within BEOL layer (which forms part of one or more signal routing layers 318). The material that forms the conductive portion of pad 312 and TSV portion 314 is identical to the material that forms the signal routing layers 318.

The pad portion 312 can overlap and laterally extend past peripheral portions of the TSV portion 314. In other words, the pad portion 312 can be wider than and fully overlap the TSV portion 314 such that, when projected to a lateral plane, the footprint of the TSV portion 314 and its lateral peripheral edges can be contained within the footprint and lateral edges of the pad portion 312.

The pad portion 312 and the TSV portion 314 can form the integral joint 316. The integral joint 316 can have consistency in the material and be integral (e.g., without structural divisions/separations) across the pad portion 312 and the TSV portion 314. The consistency and the integral nature of the joint 316 can result from forming the pad portion 312 and the TSV portion 314 through one continuous deposition step. For example, the integral interfacing structure 310 can be formed by effectively a single/continuous metallization or depositing step through the DD process (e.g., with a relatively minor adjustment to the etching mask between metallization. As a result, the integral interfacing structure 310 can have traits or structural features characteristic of DD structures, such as integral, continuous, seamless, or non-attached transitions between structure portions.

In some embodiments, the TSV portion 314 can have a narrowing via shape 320 as a result of forming the TSV portion 314 from the BS 204 toward the FS 206 and/or after a wafer thinning process. The narrowing via shape 320 can correspond to cross-sectional widths of the TSV decreasing toward the FS 306 and at portions farther from the BS 304. For example, the narrowest width of the TSV portion 314 can be at a portion closest to the FS 206, and a maximum width 324 of the TSV portion 314 can be at or immediately before the integral joint 316. As described above, the via maximum width 324 can be less than a lateral dimension of the pad portion 312. Accordingly, the side/profile shape of the TSV portion 314 can include a trapezoid with a wider top portion as illustrated in FIG. 3. In some aspects, the sidewalls of TSV portion 314 can include “scalloping” corresponding to various form of waviness.

As an illustrative example, the pad portion 312 and the TSV portion 314 can be formed by orienting the BS 304 upward, masking the BS 304, and then applying etchants through openings in the BS mask. Accordingly, the BS portions of the semiconductor wafer can have greater exposure to the applied etchants in comparison to the FS portions. As a result, the TSV portion 314 may have greater width or thickness near the BS 304.

Moreover, in some embodiments, the TSVs 214 can be formed after a wafer thinning process that removes inactive portions of the semiconductor wafer/substrate by a removed thickness 332. After the thinning process the resulting semiconductor wafer can have a final wafer thickness 334 that is less than its initial thickness by the removed thickness 332. Accordingly, the TSV portion 314 can have a via depth 326 that is equal to or less than final wafer thickness 334.

In contrast to the TSV 214 of FIG. 2, which is formed before the thinning and from the FS 206 of FIG. 2, the via depth 326 can remain unaltered. Moreover, the via depth 326 can be less than the initial via depth 230 of FIG. 2, thereby requiring less exposure to the removal mechanism (e.g., chemical etchant) to form the TSV portion 314. As a result, the via maximum width 324 of the TSV portion 314 can be less than the via maximum width 224 of FIG. 2 of the TSV 214. Moreover, since the integral interfacing structure 310 is formed after the substrate thinning step, the integral interfacing structure 310 can be formed without the via shoulder 222 of FIG. 2.

The reduction in lateral footprint/dimensions can allow the integral interfacing structure 310 to have a pad pitch 340 between the pad portions 312 and/or other external interface components. The reduction in lateral footprint/dimensions can provide the pad pitch 340 that is less than the pad pitch 240 of FIG. 2. Additionally or alternatively, the reduction in lateral footprint/dimensions can reduce or eliminate the requirement to have the dummy pads 242 of FIG. 2 laterally adjacent to the active pads or pad portions. Stated differently, the reduction in widths of the TSV portion 314 to be less than that of the pad portion 312 can allow a via pitch 342 that is equal to or less than the pad pitch 340. In comparison to the TSV 214, the TSV portion 314 can be laterally contained within the footprint of the pad portion 312. As such, the TSV portion 314 is sufficiently separated from adjacent TSVs or other TSV portions 314, and thus increase the overall signal density for the device 300 in comparison to the device 200 of FIG. 2. In some embodiments, the pad pitch 340 or targeted separation between active vertical connections can be 10 μm or less (e.g., 5 μm, 0.1 μm, etc.).

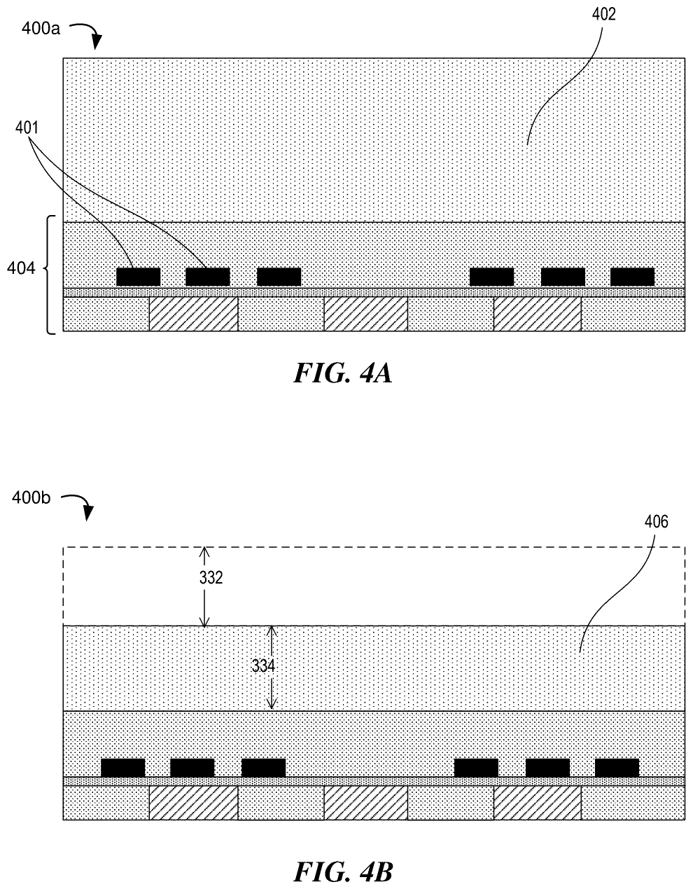

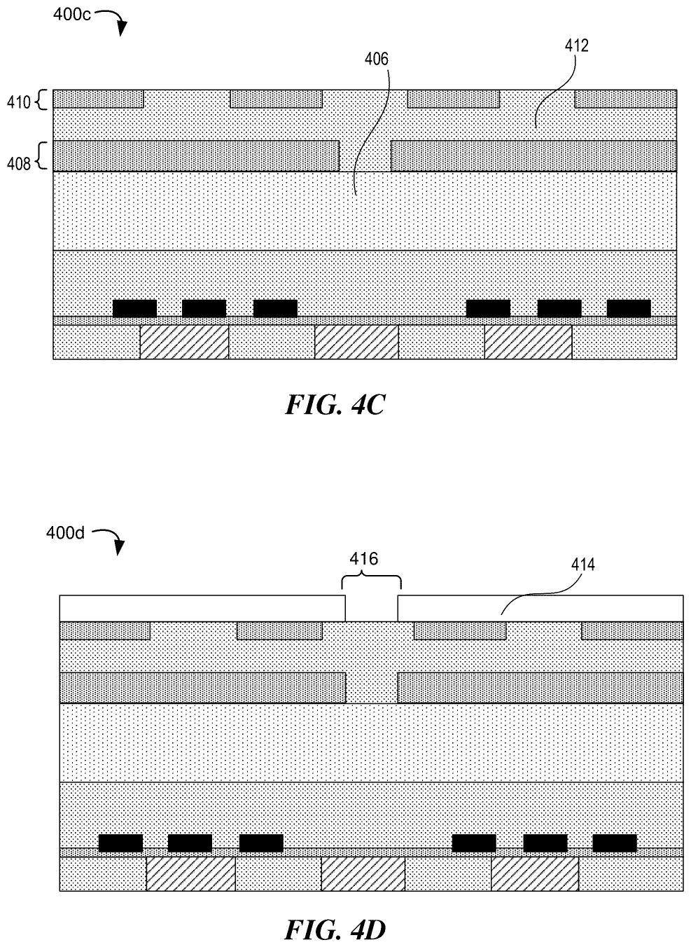

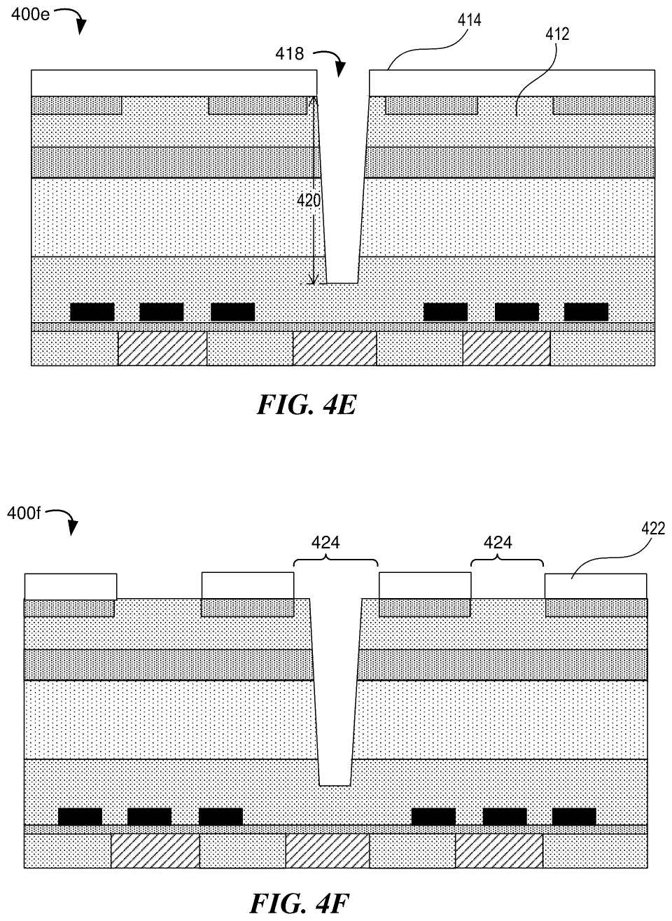

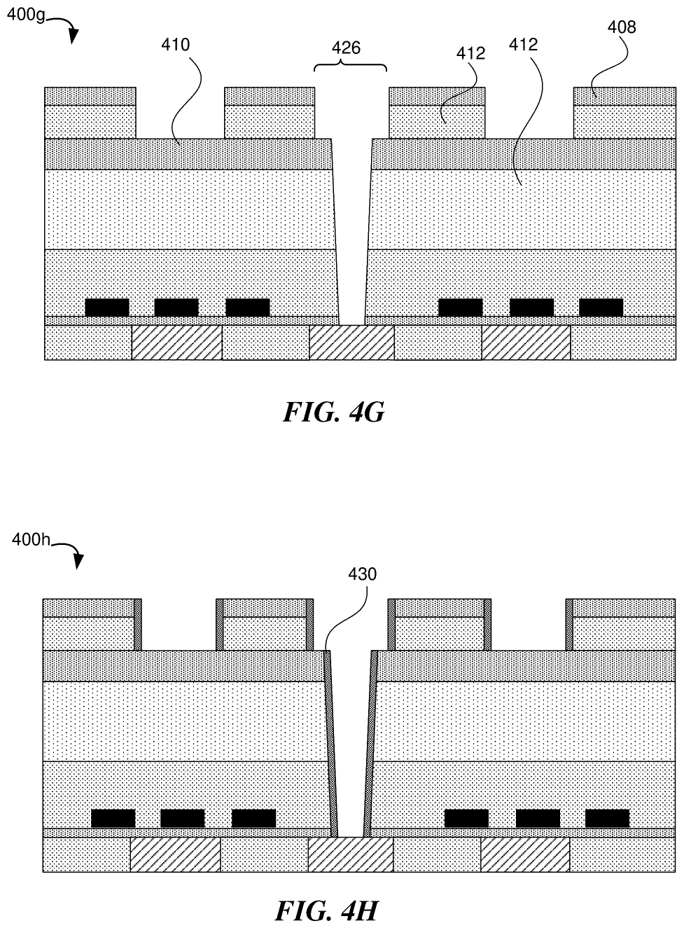

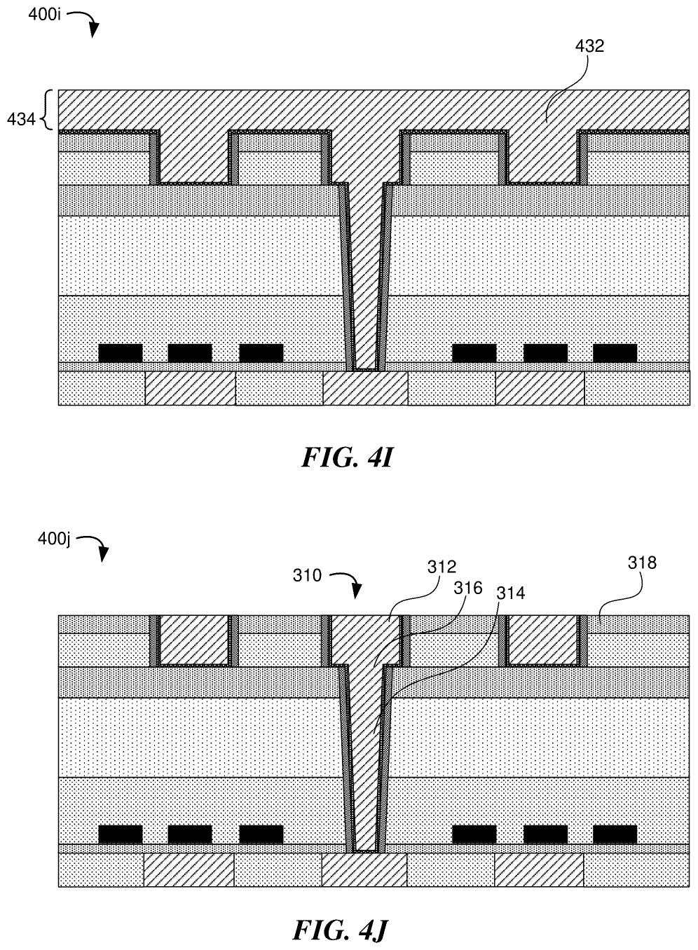

FIGS. 4A-4J are illustrations of various stages of a first example manufacturing process in accordance with an embodiment of the present technology. The example manufacturing process can be for forming one or more of the devices (e.g., the apparatus 100 of FIG. 1, the semiconductor chip 302 of FIG. 3, and/or the device 300 of FIG. 3). For example, the illustrated manufacturing process can be used to form the integral interfacing structure 310 of FIG. 3 from the BS 304 of FIG. 3 of corresponding semiconductor substrate.

FIG. 4A can illustrate an initial structure 400a having a semiconductor substrate 402 (e.g., a Si wafer) with FS components 404 thereon. For example, the semiconductor substrate 402 can have one or more dielectric layers (e.g., inter-level dielectric (ILD), such as the SiO), FS signal routing layer 318 of FIG. 3, or a combination thereof on the FS of the semiconductor substrate 402. The semiconductor substrate 402 can further have active circuitry 401 formed on the FS, such as using dopants. The initial structure 400a can correspond to a result of front-end-of-line (FEOL) manufacturing processes.

FIG. 4B can illustrate a structure 400b following a substrate thinning process. The structure 400b can have a thinned substrate 406 (e.g., a thinned Si wafer) that corresponds to the semiconductor substrate 402 of FIG. 4A. The thinned substrate 406 can be formed by removing a BS portion of the semiconductor substrate 402 by the removed thickness 332. Accordingly, the thinned substrate 406 can have the final wafer thickness 334. The BS portion of the semiconductor substrate 402 can be removed using mechanical means (e.g., grinding and/or polishing), chemical means (using, e.g., chemical etchants), or a combination thereof, such as for a chemical-mechanical planarization (CMP) process.

FIG. 4C can illustrate a structure 400c following a BS layering process. As a result, the structure 400c can include one or more control layers and/or dielectric layers (e.g., ILD) 412 formed on the BS of the thinned substrate 406. The control layers can include structures (e.g., etch stops) used to control or limit the effect of etchants during corresponding removal processes. The control layers can be used to shape subsequently formed cavities and/or material occupying such cavities (e.g., the integral interfacing structure 310 of FIG. 3). For example, the structure 400c can include (1) a first control layer 408 on the BS of the thinned substrate 406 for controlling a width of the TSV portion 314 of FIGS. 3 and (2) a second control layer 410 over the first control layer 408 for controlling a width of the pad portion 312 of FIG. 3. Accordingly, the first control layer 408 can include an opening that has a via maximum width 324, and the second control layer 410 can have openings with shapes and/or dimensions matching those of the pad portion 312. The BS layering can include laminating and/or depositing the corresponding material to form the control layer(s) and/or the dielectric layers 412.

FIG. 4D can illustrate a structure 400d following a masking process. The structure 400d can have an initial patterning layer 440 (e.g., a mask, such as a photoresist) formed over the structure 400c of FIG. 4C. The initial patterning layer 440 can include one or more initial via openings 416 that expose the corresponding portion(s) of the dielectric layer 412 underneath. The initial via openings 416 can correspond to (e.g., by overlapping in location with) the TSV portion 314 of FIG. 3. In some embodiments, the structure 400d can result from depositing or laminating an optical mask over the dielectric layer 412 and then removing portions thereof (e.g., using light) to form the initial via openings 416.

FIG. 4E can illustrate a structure 400e following a first etching process. The structure 400e can have one or more partial vias 418 formed through the corresponding via openings in the initial patterning layer 414. The partial vias 418 can extend partially through a thickness of the dielectric layer 412. The partial vias 418 can be formed by removing (e.g., using chemical etchants or laser) portions of the dielectric layer 412 through the via openings. The removal process can be controlled, such as by controlling the exposure to the removal mechanism, the amount or intensity of the removal mechanism, or a combination thereof, so that the partial vias 418 have a partial depth 420 that is less than the thickness of the substrate (e.g., less than the final wafer thickness 334 of FIG. 3).

FIG. 4F can illustrate a structure 400f following a mask adjustment process. The structure 400f can have an updated patterning layer 422 (e.g., a mask, such as a photoresist) over the structure 400e of FIG. 4E. The updated patterning layer 422 can be formed by adjusting the patterning layer 414 of FIG. 4E. For example, the updated patterning layer 422 can have pad openings 424 formed similar to the initial via opening 416 (e.g., using light or laser). One or more of the pad openings 424 may be formed by enlarging or widening the corresponding via openings 416. In some embodiments, the peripheral boundary of pad openings 424 may align with openings in the first control layer 408 of FIG. 4C.

FIG. 4G can illustrate a structure 400g following a second etching process and removal of the updated patterning layer 422 of FIG. 4F. The structure 400g can have one or more patterned depressions or cavities 426 formed by removing the dielectric layer 412 and/or the thinned substrate 406 through the updated patterning layer 422 and/or the corresponding opening(s) in the first control layer 408, the second control layer 410, or a combination thereof. At least a portion of the removal of the material (e.g., etching) can be performed using the same removal mechanism as the first etching process. In some embodiments, an additional or a separate etching may be performed (e.g., through etch stops or barrier layers) to expose electrical connections (e.g., FS pads or FS signal routing layer 318 of FIG. 3).

The patterned depressions/cavities 426 can each have portions or openings corresponding to the pad portion 312 of FIG. 3 and the TSV portion 314 of FIG. 3. The pad portion opening can correspond to a cavity in the dielectric layer 412 formed by removing the corresponding portions (e.g., ILD) through the pad opening 424 of FIG. 4F. The TSV portion opening can be extensions or enlargement of the partial via 418 of FIG. 4E and extend across or through the thickness of the thinned substrate 406. The additional exposure to the removal mechanism through the pad opening 424 can be used to extend or enlarge the partial via 418, thereby forming or completing the TSV portion opening.

FIG. 4H can illustrate a structure 400h following a preparation process. The structure 400h can have one or more initial layers 726 formed over the structure 400g of FIG. 4G. For example, the initial layers 430 can include a diffusion barrier (e.g., a tantalum (Ta) based barrier), a seed layer (e.g., initial layer of copper (Cu)), or a combination thereof. The initial layers 430 may be formed using a depositing process, such as a physical vapor deposition (PVD).

FIG. 4I can illustrate a structure 400i following a conductor depositing process, such as a metal depositing or an electroplating process. The structure 400i can have an electrical conductor (e.g., metallic structure, such as Cu) deposited over the structure 400h of FIG. 4H to form deposited structure 432. The deposited structure 432 can be formed based on the deposited material attaching to and forming over the one or more initial layers 460 of FIG. 4H, such as the seed layer.

The deposited structure 432 can have portions that correspond to the shape/portions of the structure 400h. For example, the deposited structure 432 can include one or more vertical extensions that extend along vertical directions and one or more lateral extensions integrally joined by corresponding integral joint(s) (e.g., the integral joints 316 of FIG. 3). The deposited structure 728 can have an excess portion 434 over one or more portions of the structure 700f.

FIG. 4J can illustrate a structure 400j following an excess removal process, such as a polishing process, an etching process, or a combination thereof, to remove the excess portion 434 of FIG. 4I. For example, the excess removal process can include a CMP process to form the integral interfacing structure 310 from the deposited structure 432 of FIG. 4I. Accordingly, the vertical extension of the structure 432 can correspond to the TSV portion 314, the lateral extension of the structure 432 can correspond to the pad portion 312, and the joint can correspond to the integral joint 316. Moreover, the removal of the excess portion 434 can expose portions of the first control layer 408. One or more of the steps illustrated in FIGS. 4C-4J can represent the DD.

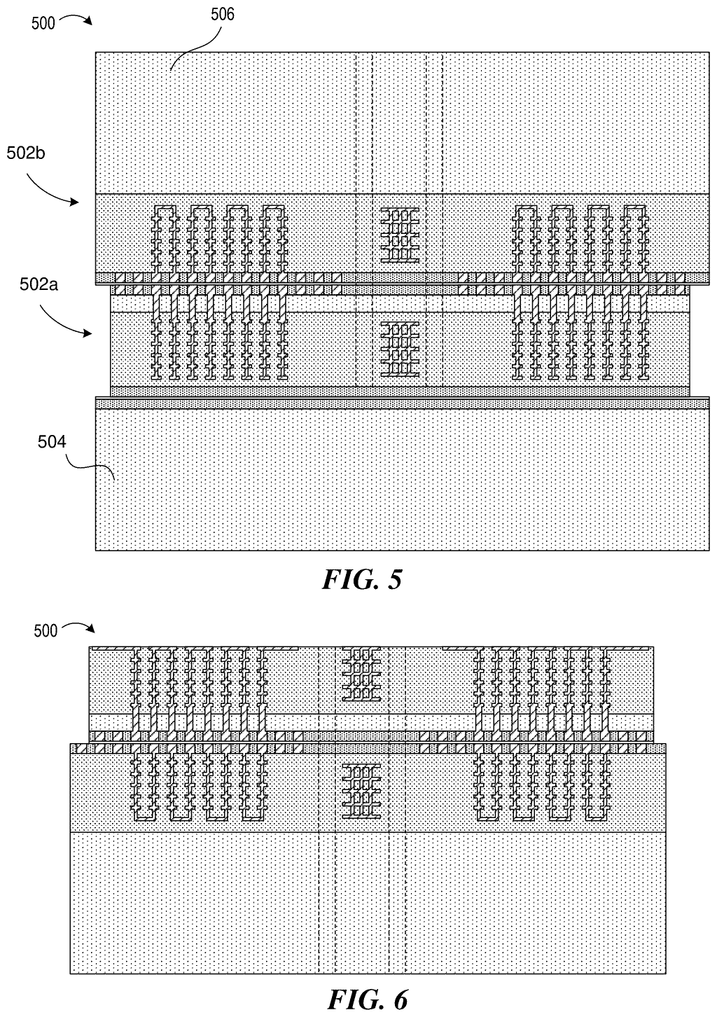

In some embodiments, the structure 400j can be used to manufacture stacked devices, packages, assemblies, or the like. FIGS. 5-11 are illustrations of various stages of a second example manufacturing process in accordance with an embodiment of the present technology.

FIG. 5 can illustrate a stacked structure 500 having two or more semiconductor devices (e.g., a set of semiconductor wafers and/or chips) stacked on top of each other. For example, the stacked structure 500 can include a second semiconductor device 502b stacked over a first semiconductor device 502a. In some embodiments, the first semiconductor device 502a and the second semiconductor device 502b can include data storage circuits (e.g., the apparatus 100 of FIG. 1, such as DRAM circuits, and/or the memory array 150 of FIG. 1 therein). One or more of the stacked devices can correspond to the structure 400j of FIG. 4J and include the integral interfacing structure 310 of FIG. 3. For example, the first semiconductor device 502a and the second semiconductor device 502b can be wafer bonded or hybrid bonded to each other with the pads and/or the pad portions 312 of FIG. 3 on the abutting faces directly contacting and/or bonded (e.g., fusion bonded) to each other.

For illustrative purposes, the second semiconductor device 502b can represent a top device, such as a device configured to be at the top of a targeted stack of devices. In some embodiments, the top device can include a thicker substrate 506 (e.g., thicker than the thinned substrate 406 of FIG. 4B) for providing structural support for the stacked structure 500. The stacked devices can be attached to and supported by a carrier wafer 504 at various phases or steps during manufacturing.

FIG. 6 can illustrate the stacked structure 500 released or removed from the carrier wafer 504 of FIG. 5 for the next processing step. FIG. 6 can illustrate the stacked structure 500 flipped or inverted from the step illustrated in FIG. 5. Once removed from the carrier wafer 504, the stacked structure 500 can have an interface surface (e.g., the FS of the semiconductor wafer) exposed. Accordingly, the stacked devices (e.g., the semiconductor devices 502a and/or 502b of FIG. 5) can be tested through the exposed interface surface.

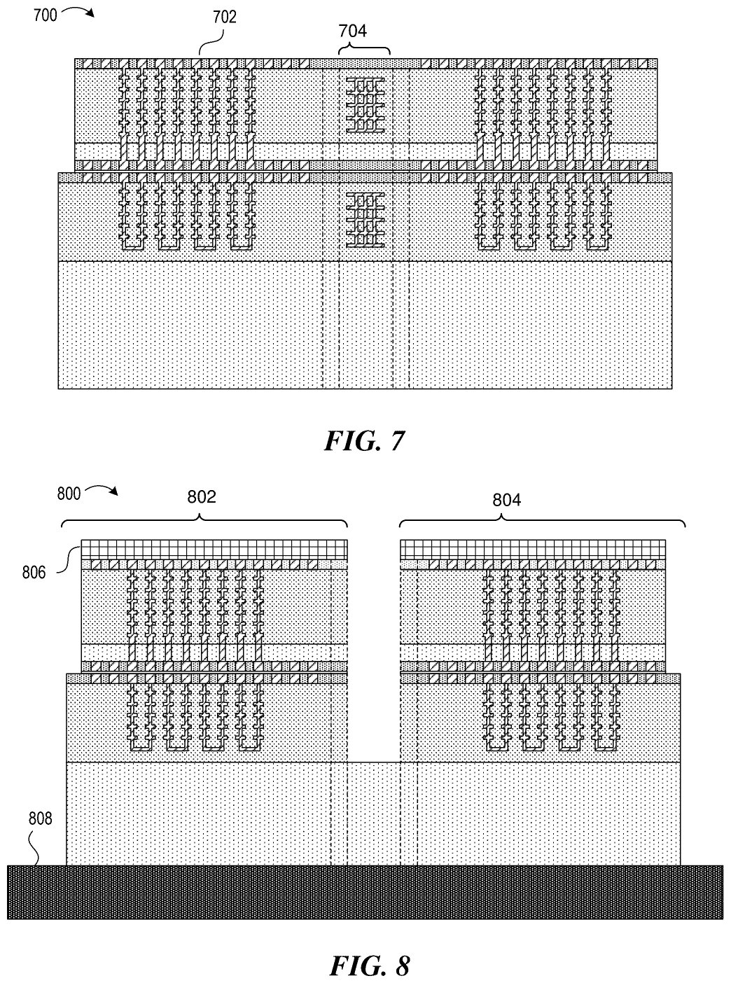

FIG. 7 can illustrate a stacked structure 700 having FS components 702 formed thereon. For example, the FS components 702 can include pads, vias, instances of the integrated interfacing structure 310 of FIG. 3, or a combination thereof formed over the exposed surface of stacked structure 500 of FIG. 6. The FS components 702 can be coupled to the active circuitry local to the corresponding semiconductor device, electrical components (e.g., the integrated interfacing structure 310) on the BS of the corresponding semiconductor device, one or more of the other stacked devices (e.g., top device), or a combination thereof.

In some embodiments, the semiconductor devices 502a and/or 502b of FIG. 5 within the stacked structure 700 can correspond to semiconductor wafers that include multiple units of circuits. The stacked structure 700 can include scribe regions or lines that separate each unit of circuits.

The stacked structure 700 (e.g., wafer stacks) can be cut or sawed along the scribe lines 704 to separate the circuit units into separate dies/chips. FIG. 8 can illustrate a stacked structure 800 resulting from the sawing process. The stacked structure 800 can have separated devices 802 and 804. When the stacked structure 700 of FIG. 7 is a wafer-bonded structure, the separated devices 802 and 804 can include stacked circuits, which can correspond to vertically stacked chips/dies.

To facilitate the sawing process, through the scribe lines 704 of FIG. 7, the stacked structure 800 can include a protective coating 806 over the FS components 702 of FIG. 7. Similarly, the stacked structure 700 can be attached to a dicing support 808 (e.g., a dicing tape). For example, the top device/wafer can be attached to the dicing support 808 and the protective coating 806 can be formed opposite the dicing support 808 and across the circuits.

In some embodiments, the stacked structure 700 may be further thinned before the sawing step. For example, the thicker substrate 506 of FIG. 5 may be reshaped to remove some of the additional wafer portions. Accordingly, the dicing support 808 can be attached to a thinned surface (e.g., surface formed after removing the excess substrate portions) of the top device/wafer.

Further, the sawing process may be performed in separate phases, such as by separating to different depths at each phase. For example, the sawing step illustrated in FIG. 8 can separate to a first depth that stops above or partially extends into the semiconductor substrate of the top device.

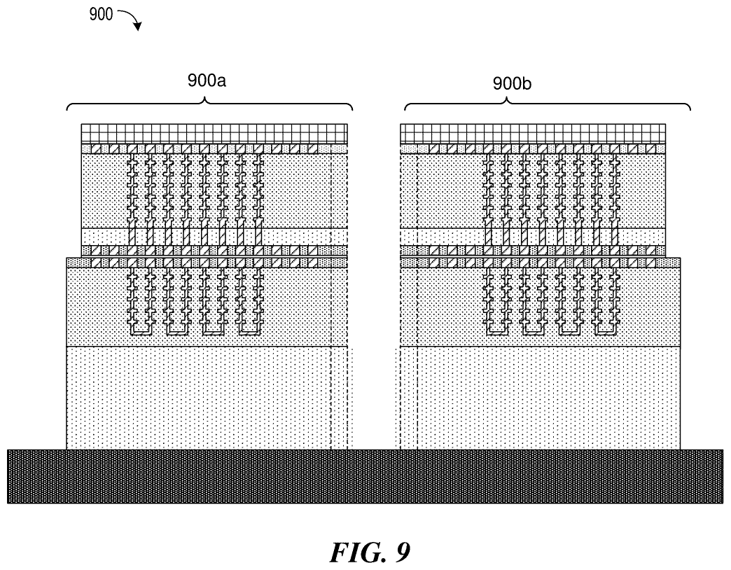

FIG. 9 can illustrate separated device stacks 900 (e.g., 900a and 900b) following the completion of the sawing process. Continuing with the illustrative example above, the subsequent sawing or separating step can finish the separation through the remaining portions of the semiconductor substrate of the top device. In some embodiments, each of the separated device stacks can include two or more semiconductor dies (e.g., memory devices, such as DRAM, or portions therein) stacked on top of each other.

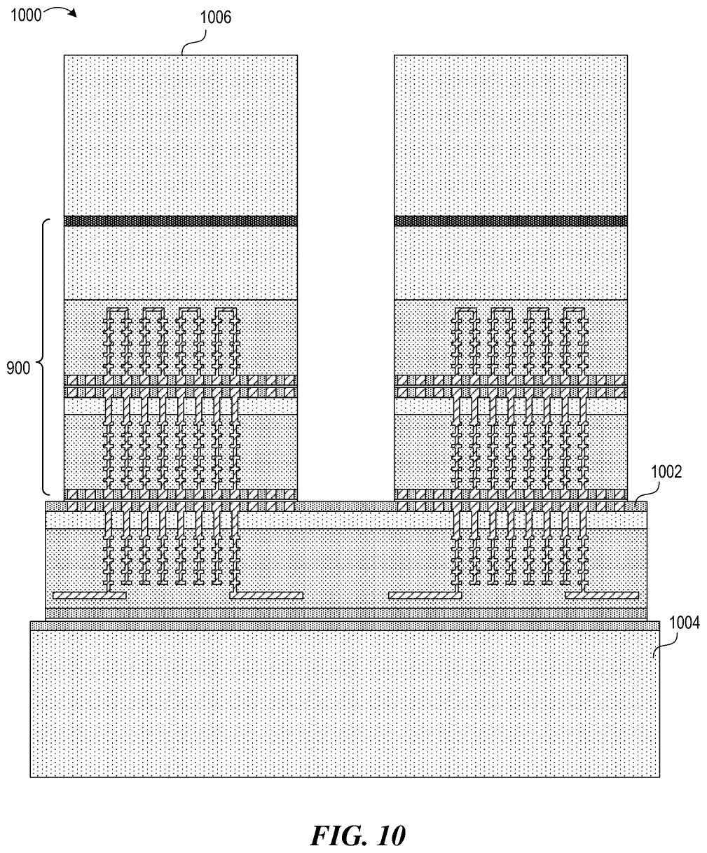

FIG. 10 can illustrate a stacked structure 1000 having the device stacks 900 of FIG. 9 attached to a common interface device 1002. The common interface device 1002 can include a semiconductor device (e.g., a chip or a wafer) including circuitry and/or logic configured to communicate with the device stacks 900. In some embodiments, the common interface device 1002 can be configured to provide external interface for the device stacks 900, such as for allowing communication between an external device and each stack and/or each die therein. For example, the common interface device 1002 can be electrically coupled between one or more processors, such as central processing units (CPUs), graphics processing units (GPUs), or the like, and one or more stacks of DRAMs. The common interface device 1002 can allow the host device(s) to access each of the DRAMs within the coupled stack(s).

As an illustrative example, the device stacks 900 can have the protective coating 806 of FIG. 8 removed after the sawing is complete. Further, the device stacks 900 can be removed from the dicing support 808 of FIG. 8 and attached (through, e.g., copper-to-wafer bonding) to the common interface device 1002. The common interface device 1002 can be attached (through, e.g., wafer-to-wafer bonding) to a carrier 1004 (e.g., Si carrier).

In some embodiments, the stacked structure 1000 can include dummy dies 1006 attached over the top dies in the device stacks 900. The dummy dies 1006 can be used to satisfy a height requirement for the overall structure. The dummy dies 1006 can include spacers that may be absent any electrical functionalities.

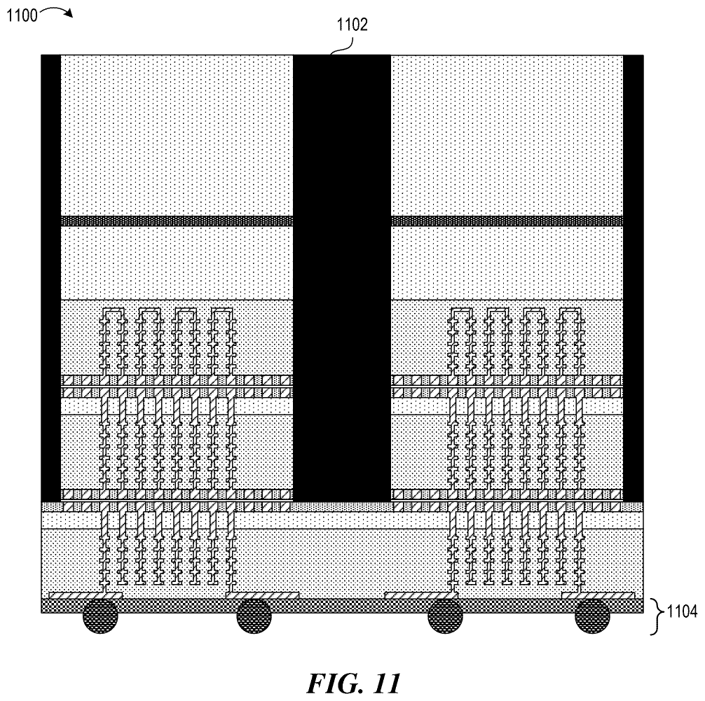

FIG. 11 can illustrate a stacked device 1100, such as a high-bandwidth memory device, following a set of finalizing steps. For example, the stacked structure 1000 of FIG. 10 can have molding 1102 formed over the common interface device 1002 of FIG. 10 and between the device stacks 900 of FIG. 9. Further, the common interface device 1002 can be sawed to singulate the units of stacked devices within the wafer. The stacked structure can be tested through the exposed surface of the common interface device 1002. Further, communication components 1104 (e.g., pads, FS signal routing layer, solder, solder resist, or the like) can be formed on the exposed side of the common interface device 1002 or the singulated equivalent thereof.

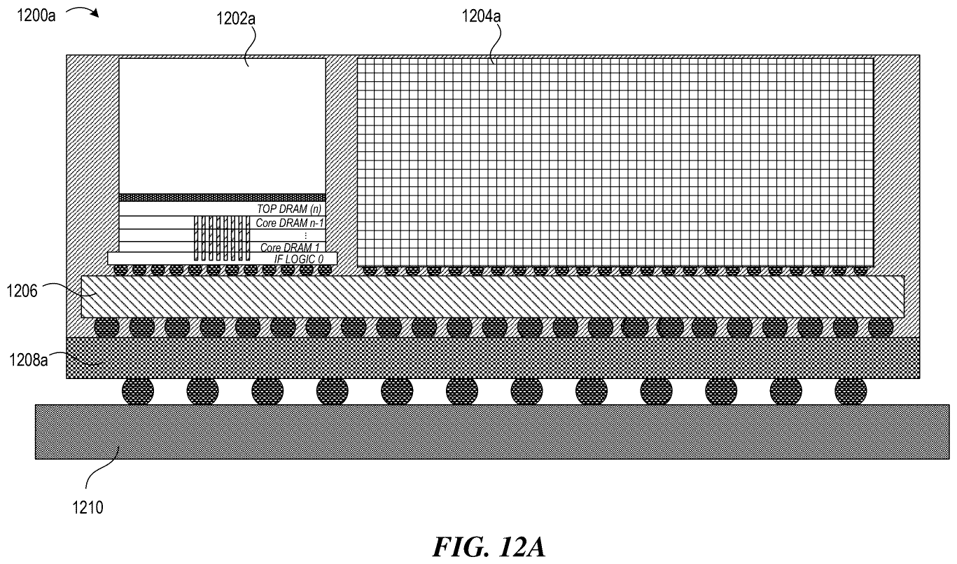

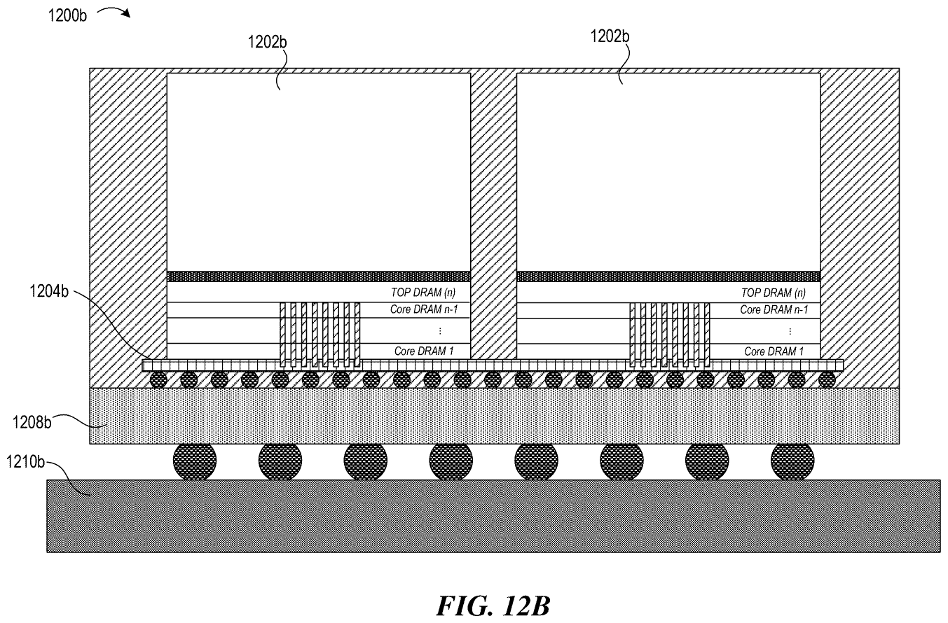

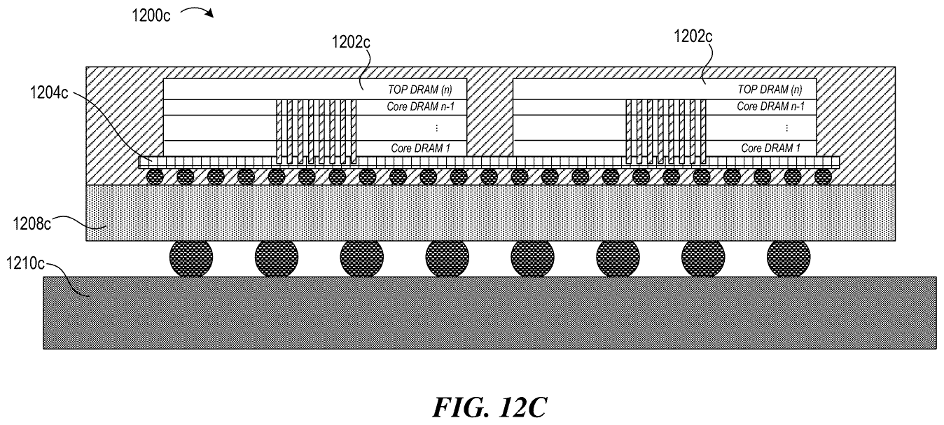

The resulting stacked device 1100 or other similar devices having the integrated interfacing structure 310 of FIG. 3 can be used to form more complex devices, such as system in package (SiP) devices. FIGS. 12A-12C are cross-sectional views of various example assemblies in accordance with an embodiment of the present technology.

FIG. 12A can illustrate a first example assembly 1200a that corresponds to a lateral configuration. For example, the first example assembly 1200a can include a stacked device 1202a (e.g., the stacked device 1100 of FIG. 11 or other similar devices having the integrated interfacing structure 310 of FIG. 3) and a local processor 1204a, such as a CPU or a GPU, mounted over an interposer 1206 (e.g., a Si interposer). The local processor 1204a and/or the stacked device 1202a (e.g., memory, such as HBM) can be attached and electrically coupled to the interposer 1206 using micro solder bumps.

In some embodiments, the stacked device 1202a can include an interface logic die on the bottom with n-/number of core memory (e.g., DRAM) devices or dies stacked thereon. The stacked device 1202a can have a top memory device/die stacked on the core memory device. For example, the stacked devices 1202a can include one, three, seven, or more core DRAMs and a top DRAM stacked over an interface logic die. The resulting stack can include two, four, eight, etc. (n=2, 4, 6, 8, or more) number of memory dies in addition to the interface device, thereby having a total of n+1 devices in the stack.

The interposer 1206 can include internal signal routing structures, such as RDL, traces, pads, and/or the like. Accordingly, the interposer 1206 can electrically couple the local processor 1204a and the stacked device 1202a to each other. For example, the interface logic die of the stacked device 1202a and the local processor 1204a can be directly mounted on the interposer 1206. The interface logic die and the local processor 1204a can have contacts, pads, posts, that are communicatively coupled with the corresponding signal routing structures on the interposer 1206.

Additionally or alternatively, the interposer 1206 can couple the local processor 1204a and/or the stacked device 1202a to components attached below the interposer 1206, such as a package substrate 1208a. The local processor 1204a, the stacked device 1202a, the interposer 1206, portions thereof, or a combination thereof can be encased in molding. Accordingly, the local processor 1204a, the stacked device 1202a, the interposer 1206, and the package substrate 1208a can form a semiconductor package. The corresponding package can be attached or mounted over a system substrate 1210a, such as a printed circuit board (PCB).

FIG. 12B can illustrate a second example assembly 1200b that corresponds to a first vertical configuration. For example, the second example assembly 1200b can include one or more stacked devices 1202b (e.g., the stacked device 1100 of FIG. 11, the devices stacks 900 of FIG. 9, or other similar devices having the integrated interfacing structure 310 of FIG. 3) stacked or directly mounted on a local processor 1204b, such as a CPU or a GPU. Referencing the examples described above, the device stacks 900 or the stacked device 1100 can be mounted or bonded directly over the local processor 1204b, similarly as described with reference to FIG. 10 and FIG. 11. The local processor 1204 can include external interfaces, such as posts, pads, traces, etc., on a top portion thereof for communicatively coupling with the stacked device(s) 1202b. In comparison to the first example assembly 1200a, the second example assembly 1200b can use the direct communication between the local processor 1204 and the stacked device(s) 1202b to replace the interposer 1206 of FIG. 12A.

Each stacked device 1202b can include n number of functional devices (e.g., memory dies) that include a top device stacked over n-/number of core devices. For example, the stacked device 1202b can include one, three, seven, or more core DRAMs and a top DRAM. In contrast to the stacked device 1202a of FIG. 12A, the stacked device 1202b can have the bottom core device (e.g., core DRAM 1) directly mounted to and directly communicatively coupled (e.g., without the interposer 1206) to the local processor 1204. Based on the direct communication between the core device and the local processor, the stacked device 1202b can include n number of devices instead of the n+1 number of devices for the stacked device 1202a.

The vertically stacked arrangement of the local processor 1204 and the stacked device(s) 1202b can be mounted on a package substrate 1208b. Further, the local processor 1204b and the stacked device(s) 1202b can be encased in molding. Accordingly, the local processor 1204b, the stacked device(s) 1202b, and the package substrate 1208b can form a semiconductor package. The corresponding package can be attached or mounted over a system substrate 1210b, such as a printed circuit board (PCB).

FIG. 12C can illustrate a third example assembly 1200c that corresponds to a second vertical configuration. The third example assembly 1200c can be similar to the second example assembly 1200b of FIG. 12B. For example, the third example assembly 1200c can include one or more stacked devices 1202c (e.g., the stacked device 1100 of FIG. 11, the device stacks 900 of FIG. 9, or other similar devices having the integrated interfacing structure 310 of FIG. 3) stacked or directly mounted on a local processor 1204c, such as a CPU or a GPU. Also, each stacked device 1202c can include n total number of devices (e.g., DRAMs) with n-/number of core devices and one top device. The third example assembly 1200c can further include a package substrate 1208c, molding, and/or the system substrate 1210b.

In comparison to the second example assembly 1200b, the third example assembly 1200c can have the stacked devices 1202c having lower height/profile than the stacked devices 1202b of FIG. 12B. For example, the stacked devices 1202c can be without dummy dies and/or have inactive portions of one or more of the stacked dies (e.g., the top die) removed, such as through the thinning process described above, to produce the lower height.

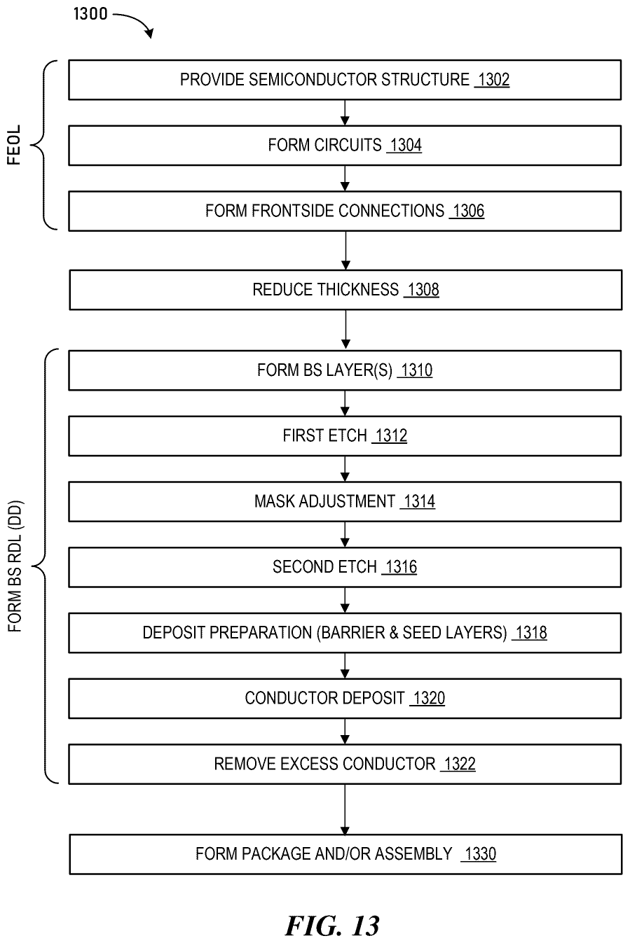

FIG. 13 is a flow diagram illustrating an example method 1300 of manufacturing a semiconductor device (e.g., the apparatus 100 of FIG. 1, the stacked device 1100 of FIG. 11, the device stacks 900 of FIG. 9, the systems/packages/assemblies of FIGS. 12A-C, or other devices having the integrated interfacing structure 310 of FIG. 3) in accordance with an embodiment of the present technology. For example, the example method 1300 can correspond to forming the integrated interfacing structure 310. The example method 1300 can correspond to the process described above and the structures illustrated in one or more of FIG. 4A-FIG. 11.

At block 1302, the method 1300 can include providing a semiconductor structure, such as a semiconductor substrate of FIG. 3 and/or the initial substrate 402 of FIG. 4A. The semiconductor structure can have an active side or a FS and a BS. At block 1304, the method 1300 can include forming active circuitry at or nearer to the FS. The active circuitry can be formed by masking, depositing dopants, layering, and/or forming other electrical components on or near the FS. At block 1306, the method 1300 can further include forming the FS electrical connections, such as the FS signal routing layer 318 of FIG. 3 or the or the corresponding portions. The FS electrical connections can be formed by building layers of IDL, forming patterned masks, depositing conductive material according to the predetermined pattern, and/or the like. In some embodiments, blocks 1302-1306 can correspond to FEOL manufacturing processes. Further, one or more of the blocks 1302-1306 can correspond to the manufacturing processes for forming the initial structure 400a of FIG. 4A.

After forming the active circuitry and FS connections, the method 1300 can include reducing the thickness of the semiconductor structure, as illustrated at block 1308. The thickness reduction process can correspond to the substrate thinning process and the resulting structure 400b described above for FIG. 4B. For example, excess portions on or near the BS of the initial substrate 402 can be removed, such as by mechanical and/or chemical means, to reduce the thickness by the removed thickness 332 of FIG. 4B. As a result, the initial substrate 402 can be thinned to form the thinned substrate 406 of FIG. 4B having the final wafer thickness 334 of FIG. 4B.

At block 1310, the method 1300 can include forming one or more layers, such as by depositing the dielectric layer 412 of FIG. 4C, the control layers of FIG. 4, or the like on the BS of the semiconductor structure. Block 1310 can correspond to the process described above for forming the structure 400c of FIG. 4C. Block 1310 can further include forming an etch mask (e.g., the initial patterning layer 414), such as described above regarding the structure 400d of FIG. 4D.

At block 1312, the method 1300 can include implementing a first etching process using the formed mask to partially etch portions of the corresponding structure, such as described above regarding the structure 400e of FIG. 4E. At block 1314, the method 1300 can include implementing a mask adjustment process corresponding to the structure 400f of FIG. 4F. At block 1316, the method 1300 can include a second etching process using the adjusted mask, such as described above for structure 400g of FIG. 4G. At block 1318, the method 1300 can include a preparation process for the patterned structure in advance of a depositing process. Block 1318 can correspond to the process described for the structure 400h of FIG. 4H. Following the preparation, at block 1320, the method 1300 can include a conductor depositing process corresponding to the structure 400i of FIG. 4I. At block 1322, the method 1300 can include an excess removal process to shape the deposited conductor, such as described above for the structure 400j of FIG. 4J. In some embodiments, blocks 1312-1322 can correspond to the DD process, such as used for forming the integral interfacing structure 310.

At block 1330, the method 1300 can include forming packages and/or assemblies using the result of the process represented by block 1322. For example, block 1322 can correspond to dicing wafers, attaching the wafers/dies over supported structures (e.g., other instances of the semiconductor devices 502 of FIG. 5 like other memory devices, the common interface device 1002 of FIG. 10, the processors 1204b/c of FIGS. 12B and 12C, or the like as described above for FIGS. 5-11. Accordingly, the processes represented by block 1330 can be used to form a semiconductor chip (e.g., a memory die), a stack of memory dies, a stacked memory package (e.g., the HBM), or a package (e.g., SiP) that include and utilize the integral interfacing structure 310 for to communicatively couple circuits along the different circuit layers/vertical directions.

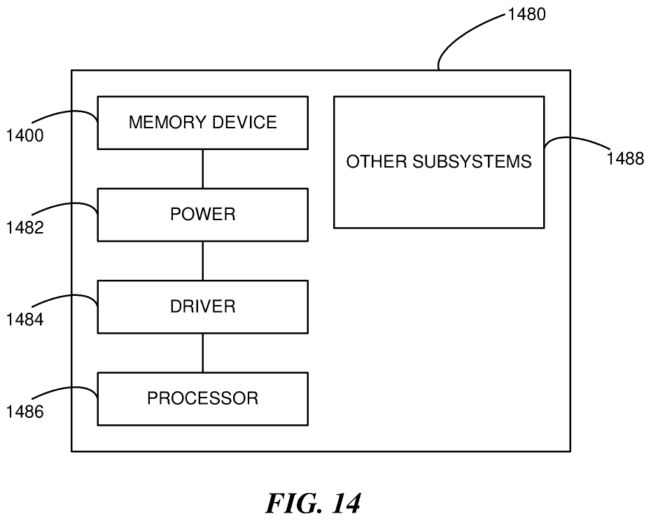

FIG. 14 is a schematic view of a system that includes an apparatus in accordance with embodiments of the present technology. Any one of the foregoing apparatuses (e.g., memory devices) described above with reference to FIGS. 1-8 can be incorporated into any of a myriad of larger and/or more complex systems, a representative example of which is system 1480 shown schematically in FIG. 14. The system 1480 can include a memory device 1400, a power source 1482, a driver 1484, a processor 1486, and/or other subsystems or components 1488. The memory device 1400 can include features generally similar to those of the apparatus described above with reference to FIGS. 1-13, and can therefore include various features for performing a direct read request from a host device. The resulting system 1480 can perform any of a wide variety of functions, such as memory storage, data processing, and/or other suitable functions. Accordingly, representative systems 1480 can include, without limitation, hand-held devices (e.g., mobile phones, tablets, digital readers, and digital audio players), computers, vehicles, appliances and other products. Components of the system 1480 may be housed in a single unit or distributed over multiple, interconnected units (e.g., through a communications network). The components of the system 1480 can also include remote devices and any of a wide variety of computer readable media.

From the foregoing, it will be appreciated that specific embodiments of the technology have been described herein for purposes of illustration, but that various modifications may be made without deviating from the disclosure. In addition, certain aspects of the new technology described in the context of particular embodiments may also be combined or eliminated in other embodiments. Moreover, although advantages associated with certain embodiments of the new technology have been described in the context of those embodiments, other embodiments may also exhibit such advantages and not all embodiments need necessarily exhibit such advantages to fall within the scope of the technology. Accordingly, the disclosure and associated technology can encompass other embodiments not expressly shown or described herein.

In the illustrated embodiments above, the apparatuses have been described in the context of DRAM devices. Apparatuses configured in accordance with other embodiments of the present technology, however, can include other types of suitable storage media in addition to or in lieu of DRAM devices, such as, devices incorporating NAND-based or NOR-based non-volatile storage media (e.g., NAND flash), magnetic storage media, phase-change storage media, ferroelectric storage media, etc.

The term “processing” as used herein includes manipulating signals and data, such as writing or programming, reading, erasing, refreshing, adjusting or changing values, calculating results, executing instructions, assembling, transferring, and/or manipulating data structures. The term data structure includes information arranged as bits, words or code-words, blocks, files, input data, system-generated data, such as calculated or generated data, and program data.

The above embodiments are described in sufficient detail to enable those skilled in the art to make and use the embodiments. A person skilled in the relevant art, however, will understand that the technology may have additional embodiments and that the technology may be practiced without several of the details of the embodiments described above with reference to FIGS. 1-14.

I/we claim:

1. A semiconductor device, comprising:
a semiconductor substrate having a front portion opposite a back portion;
active circuitry formed in or on the semiconductor substrate and located closer to the front portion than the back portion; and
an integral electrical connector overlapping the back portion, the integral electrical connector having a pad portion integrally joined with a through-silicon via (TSV) portion that extends at least partially through the semiconductor substrate,
wherein the pad portion is configured to provide external electrical interface,
wherein the TSV portion is configured to extend the external electrical interface at least partially through the semiconductor substrate, and
wherein the TSV portion has a narrowing via shape.

2. The semiconductor device of claim 1, wherein the integral electrical connector includes one or more characteristics resulting from a dual-damascene process used to form the integral electrical connector.

3. The semiconductor device of claim 1, wherein the narrowing via shape is characteristic of forming the TSV portion based on etching a corresponding cavity from the back portion toward the front portion.

4. The semiconductor device of claim 3, wherein:
the pad portion has a pad width measured along a lateral direction; and
the TSV portion has a maximum via width measured along the lateral direction, wherein the maximum via width is less than the pad width as a characteristic of forming the corresponding cavity after thinning the semiconductor substrate.

5. The semiconductor device of claim 3, wherein:
the semiconductor substrate, the active circuitry, and the integral electrical connector comprise a first memory die; and
further comprising:
a second memory die stacked over the first memory die, wherein the second memory die is attached and electrically coupled to the pad portion.

6. The semiconductor device of claim 5, further comprising:
an interposer below the first memory die; and
a processor mounted on the interposer, wherein the processor is electrically coupled to the first and second memory dies through the interposer.

7. The semiconductor device of claim 5, further comprising:
a processor below the first memory die, wherein the processor is directly attached to the first memory die and electrically coupled to the first and/or second memory dies.

8. The semiconductor device of claim 1, wherein:
the pad portion corresponds to a first contact pad; and
further comprising:
a second contact pad (1) coplanar with the first contact pad, (2) directly adjacent to the first contact pad, and (3) separated from the first contact pad according to a pad pitch less than 10 μm.

9. The semiconductor device of claim 1, wherein the active circuitry includes memory cells configured to store data.

10. The semiconductor device of claim 9, wherein the semiconductor device comprises a dynamic random-access memory (DRAM).

11. A method of manufacturing a semiconductor device, the method comprising:
providing a semiconductor substrate having a front portion opposite a back portion; and
forming an integral electrical connector on the back portion of the semiconductor substrate, the integral electrical connector having a pad portion integrally joined with a through-silicon via (TSV) portion that extends at least partially through the semiconductor substrate,
wherein the pad portion is configured to provide external electrical interface,
wherein the TSV portion is configured to extend the external electrical interface at least partially through the semiconductor substrate, and
wherein the TSV portion has a narrowing via shape.

12. The method of claim 11, further comprising:
thinning the semiconductor substrate by removing a segment of the back portion, wherein the integral electrical connector is formed on the back portion of the thinned substrate.

13. The method of claim 11, wherein forming the integral electrical connector includes forming the pad portion and the TSV portion through a single continuous process.

14. The method of claim 13, wherein the pad portion and the TSV portion are formed by continuously depositing electrically conductive material into a corresponding patterned cavity that extends at least partially through the semiconductor substrate from the back portion thereof.

15. The method of claim 14, wherein forming the integral electrical connector includes utilizing a dual damascene process.

16. The method of claim 15, wherein forming the integral electrical connector includes:
forming an initial patterning layer over the back portion, wherein the initial patterning layer includes an initial via opening;
forming the initial via opening on the back portion based on etching through the initial via opening, wherein the initial via opening extends towards the front portion;
adjusting the initial via opening to form a pad opening after forming the initial via opening; and
forming the patterned cavity based on etching through the pad opening, wherein forming the patterned cavity includes extending the initial via opening further toward the front portion; and
depositing the electrically conductive material into the patterned cavity.

17. The method of claim 11, wherein:
the semiconductor substrate is a first semiconductor wafer;
further comprising:
stacking a second semiconductor wafer over the first semiconductor wafer,
wherein the first and second semiconductor wafers are directly bonded to each other,
wherein the first and second semiconductor wafers each include local memory cells, and
wherein the first and second semiconductor wafers are electrically coupled to each other through the integral electrical connector; and
dicing the first and second semiconductor wafers to form a stack of memory dies.

18. The method of claim 17, further comprising:
mounting the stack of memory dies on an interposer; and
mounting a processor on the interposer, wherein the processor is electrically coupled to the stack of memory dies through the interposer.

19. The method of claim 17, further comprising:
mounting the stack of memory dies directly on a processor.

20. A memory device, comprising:
a stack of memory dies including at least a first die stacked on and wafer bonded to a second die, the stack of memory dies including memory cells configured to store data, wherein:
the first die includes a first pad facing the second die; and
the second die having an integral electrical connector on a backside of the second die, the integral electrical connector having (1) a pad portion directly attached to the first pad and (2) a through-silicon via (TSV) portion that extends at least partially through a thickness of the second die,
wherein the pad portion and the TSV portion form an integral joint that maintains a consistent density and a continuity across the pad portion and the TSV portion, and
wherein the TSV portion has lateral cross-sectional widths that is (1) less than a lateral dimension of the pad portion and (2) decrease at locations farther away from the pad portion.
